(19) United States
(12) Patent Application Publication
(10) Pub. No.: US 2026/0324262 A1
(43) Pub. Date: Oct. 15, 2026

(54) DISPLAY APPARATUS

(71) Applicant: LG Display Co., Ltd., Seoul (KR)

(72) Inventors: Geon Hyeong KIM, Paju-si (KR); Ho Yoon Jung, Paju-si (KR); Ji Ho Son, Paju-si (KR)

(21) Appl. No.: 19/467,671

(22) Filed: Feb. 2, 2026

(30) Foreign Application Priority Data
Mar. 31, 2025 (KR) 10-2025-0041597

(51) Int. Cl. H10K 59/80

(52) U.S. Cl. CPC H10K 59/878; H10K 59/873; H10K 59/8792

(57) ABSTRACT

A display apparatus includes a display panel configured to display an image, a cover glass disposed over the display panel, and a first reflective material layer disposed on a side surface of the cover glass.

### CROSS REFERENCE TO RELATED APPLICATION

This application claims priority from and the benefit of Korean Patent Application No. 10-2025-0041597, filed on Mar. 31, 2025, which is hereby incorporated by reference for all purposes as if fully set forth herein.

### BACKGROUND

### FIELD

Embodiments of the invention relate generally to a display apparatus, and more particularly, to a display apparatus capable of preventing a light leakage phenomenon and defects in various sensors.

### DISCUSSION OF THE BACKGROUND

Image display apparatuses, which render a variety of information on a screen, are core technologies of the information communication age, and are being developed toward reduced thinness, reduced weight, greater portability, and higher performance. As such, display apparatuses that can be manufactured to have a light and thin structure are receiving increasing attention.

As concrete examples of such a display apparatus, there are a liquid crystal display (LCD) apparatus, a quantum dot (QD) display apparatus, a field emission display (FED) apparatus, an organic light emitting diode (OLED) display apparatus, etc.

Among these display apparatuses, the OLED display apparatus is a self-luminous display apparatus and, as such, is not only advantageous in terms of power consumption according to low-voltage driving, but also has excellent color rendering, fast response time, wide

viewing angle, and high contrast ratio (CR). In this regard, research on OLED display apparatuses is being conducted.

The OLED display apparatus with these advantages is increasingly being used in recent mobile and IT products. These mobile and IT products may be equipped with various components such as an infrared (IR) sensor, an ambient light sensor (ALS), a camera, a speaker, etc.

Since both the cover glass and the display panel of the OLED display apparatus used in mobile and IT products are made of glass, persistent light leakage may always occur at an edge of the glass. This light leakage may cause defects in various components disposed in the display apparatus, such as an infrared (IR) sensor, an ambient light sensor (ALS), a camera, a speaker, etc. (in particular, defects in the ambient light sensor).

The above information disclosed in this Background section is only for understanding of the background of the inventive concepts, and, therefore, it may contain information that does not constitute prior art.

### SUMMARY

A display apparatus according to embodiments of the invention is capable of preventing a light leakage phenomenon in an edge region of a cover glass and defects in various sensors in the display apparatus.

Additional features of the inventive concepts will be set forth in the description which follows, and in part will be apparent from the description, or may be learned by practice of the inventive concepts.

According to an embodiment of the present disclosure, a display apparatus

includes a display panel configured to display an image, a cover glass disposed over the display panel, and a first reflective material layer disposed on a side surface of the cover glass.

The first reflective material layer may be disposed on all side surfaces of the cover glass.

The first reflective material layer may be disposed to cover all side surfaces of the cover glass and a portion of a bottom surface of the cover glass adjacent to the side surface of the cover glass.

The display apparatus may further include a second reflective material layer disposed on a surface of the display panel.

The first reflective material layer or the second reflective material layer may include silver (Ag).

The first reflective material layer or the second reflective material layer may be formed of a combination of materials selected from SiO₂, TiO₂, silver (Ag), and aluminum (Al) to have a multilayer structure.

The first reflective material layer or the second reflective material layer may have a thickness of about 400 to about 800 Å.

According to an embodiment of the present disclosure, the display apparatus may further include a black coating layer disposed on a lower surface of the display panel, a back plate disposed on a lower surface of the black coating layer, and a polarization layer disposed on an upper surface of the display panel. The cover glass may be attached to the polarization layer by an adhesive layer.

According to an embodiment of the present disclosure, the display apparatus may further include a black matrix disposed on a back surface of the cover glass.

The black matrix may be disposed on a portion of the back surface of the cover glass where the adhesive layer is not formed.

The black matrix and the adhesive layer overlap each other in a predetermined region.

The black matrix may include a first black matrix disposed to cover a side surface of the first reflective material layer and the back surface of the cover glass, and a second black matrix disposed on a back surface of the first black matrix.

The black matrix may include a first black matrix disposed on the back surface of the cover glass while overlapping an end of the first reflective material layer disposed on the back surface of the cover glass, and a second black matrix disposed on a back surface of the first black matrix.

According to another embodiment of the present disclosure, a display apparatus includes: a display panel configured to display an image, a cover glass disposed over the display panel, a first reflective material layer disposed on side and bottom surfaces of the cover glass, and a second reflective material layer disposed on a surface of the display panel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic block diagram showing a display apparatus according to an embodiment of the present disclosure.

FIG. 2 is a schematic circuit diagram of a pixel included in the display apparatus according to an embodiment of the present disclosure.

FIG. 3 is a schematic plan view of a display apparatus according to an embodiment of the present disclosure.

FIG. 4 is a schematic cross-sectional view of the display apparatus according to an embodiment of the present disclosure taken along line I-I' in FIG. 3.

FIG. 5 is a detailed schematic configuration diagram of part "A" of FIG. 4 according to an embodiment of the present disclosure.

FIG. 6 is a detailed schematic configuration diagram of part "A" of FIG. 4 according to another embodiment of the present disclosure.

FIG. 7 is a detailed schematic configuration diagram of part "A" of FIG. 4 according to another embodiment of the present disclosure.

FIG. 8 is a detailed schematic configuration diagram of part "A" of FIG. 4 according to another embodiment of the present disclosure.

FIG. 9 is a schematic cross-sectional view of an arbitrary pixel disposed in an active area of a display panel according to an embodiment of the present disclosure.

FIG. 10 is a schematic cross-sectional view of a display apparatus according to another embodiment of the present disclosure taken along line I-I' in FIG. 3.

FIGS. 11A and 11B are schematic results of a simulation associated with light loss in a display apparatus according to an embodiment of the present disclosure and a

comparative example.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

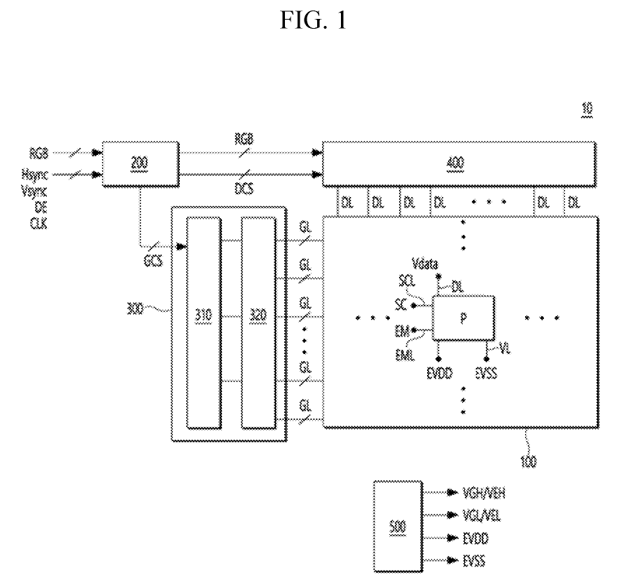

FIG. 1 is a schematic block diagram showing a display apparatus according to an embodiment of the present disclosure.

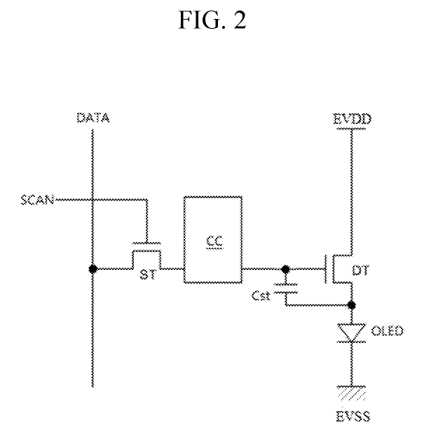

FIG. 2 is a schematic circuit diagram of a pixel included in the display apparatus according to an embodiment of the present disclosure.

As shown in FIG. 1, the display apparatus 10 may include a display panel 100 including a plurality of pixels P, a controller 200, a gate driving circuit 300 configured to supply a gate signal to each of the plurality of pixels P, a data driving circuit 400 configured to supply a data signal (or a data voltage) to each of the plurality of pixels P, and a power supply 500 configured to supply electric power to each of the plurality of pixels P, for driving of each of the plurality of pixels P.

The display panel 100 may include an active area in which the pixels P are disposed, and a non-active area disposed to surround the active area. In the non-active area, the gate driving circuit 300 and the data driving circuit 400 can be disposed. In one embodiment, the gate driving circuit 300 and the data driving circuit 400 may be disposed left portion and the upper portion of the pixels P. However, in another embodiment, the gate driving circuit 300 and the data driving circuit 400 may be disposed any portions around (or adjacent to) the pixels P.

A plurality of gate lines GL and a plurality of data lines DL may intersect each other at the display panel 100, and each of the plurality of pixels P may be connected to corresponding ones of the gate lines GL and the data lines DL. In detail, each pixel P may receive a gate signal from the gate driving circuit 300 through the corresponding gate line GL, receive a data signal from the data driving circuit 400 through the corresponding data line DL, and receive a high-level drive voltage EVDD and a low-level drive voltage EVSS from the power supply 500.

Each gate line GL may supply a scan signal SC and an emission control signal EM to a plurality of pixels P, and each data line DL may supply a data voltage Vdata to a plurality of pixels P. According to one or more embodiments, each gate line GL may include a plurality of scan lines SCL for supply of the scan signal SC, and a plurality of emission control signal lines EML for supply of the emission control signal EM.

As shown in FIG. 2, each pixel P may include a switching transistor ST, a driving transistor DT, a compensation circuit CC, a light emitting element OLED, and a storage capacitor Cst.

The light emitting element OLED may operate to emit light according to a drive current formed by the driving transistor DT.

The switching transistor ST may perform a switching operation to store a data signal supplied through a data line DL in the storage capacitor Cst as a data voltage corresponding to a scan signal supplied through a gate line GL.

The driving transistor DT may operate to enable a constant drive current to flow between a power line for the high-level drive voltage EVDD and a power line for the low-level drive voltage EVSS corresponding to the data voltage stored in the storage capacitor Cst.

The compensation circuit CC may be a circuit configured to compensate a threshold voltage, etc. of the driving transistor DT. The compensation circuit CC may include one or more thin film transistors and at least one capacitor. The configuration of the compensation circuit CC may be diverse according to compensation methods.

Although the pixel P shown in FIG. 2 is configured to have, for example, a 2T(transistor)-1C(capacitor) structure including the switching transistor ST, the driving transistor DT, the storage capacitor Cst, and the light emitting element OLED, in other embodiments, the pixel P may be diversely configured to have structures of 3T-1C, 4T-2C, 5T-2C, 6T-1C, 7T-1C, 7T-2C, etc. when the compensation circuit CC is added.

The display panel 100 may be implemented as a non-transmissive display panel or a transmissive display panel. The transmissive display panel may be applied to a transparent display apparatus in which an image is displayed on a screen and through which an actual background is visible. The display panel 100 may be implemented as a flexible display panel. The flexible display panel may be implemented as an OLED panel using a plastic substrate.

Each pixel P may be divided into a red subpixel, a green subpixel, and a blue subpixel, for color rendering. Each pixel P may further include a white subpixel. Each subpixel may include a pixel circuit.

Light emitting elements OLED disposed at the red subpixel, the green subpixel, and the blue subpixel may emit red light, green light, and blue light, respectively. The light emitting element OLED disposed at each of the red subpixel, the green subpixel, and the blue subpixel may emit white light. A red color filter, a green color filter, or a blue color filter may be disposed at each subpixel.

Touch sensors may be disposed on the display panel 100. Touch input may be sensed using separate touch sensors or may be sensed through the pixels P. The touch sensors may be disposed on a screen of the display panel 100 in an on-cell type or an add-on type or may be implemented as in-cell type touch sensors built in the display panel 100.

The controller 200 may process image data RGB input thereto from an outside thereof, to match the size and resolution of the display panel 100, and then supply the processed image data RGB to the data driving circuit 400. The controller 200 may generate a gate control signal GCS and a data control signal DCS using synchronization signals input from the outside thereof, for example, a dot clock signal CLK, a data enable signal DE, a horizontal synchronization signal Hsync, and a vertical synchronization signal Vsync.

The controller 200 may supply the gate control signal GCS to the gate driving circuit 300, thereby controlling an operation timing of the gate driving circuit 300. The controller 200 may supply the data control signal DCS to the data driving circuit 400, thereby controlling an operation timing of the data driving circuit 400. The controller 200 may synchronize operation timings of the gate driving circuit 300 and the data driving circuit 400 using the gate control signal GCS and the data control signal DCS.

The controller 200 may be configured to be coupled with various processors, for example, a microprocessor, a mobile processor, an application processor, etc. according to a device mounted therein.

A host system, which is connected to the controller 200, may be one of a television (TV) system, a set-top box, a navigation system, a personal computer (PC), a home theater system, a mobile appliance, a wearable appliance, and a vehicle system.

The controller 200 may multiply an input frame frequency by i times, thereby controlling the operation timings of the display panel drivers at a frame frequency corresponding to an “input frame frequency x i” Hz (i being a positive integer greater than 0). The input frame frequency is about 60 Hz in a national television standards committee (NTSC) system, and is about 50 Hz in a phase-alternating line (PAL) system.

The controller 200 may drive each pixel P at various refresh rates. The controller 200 may drive each pixel P in a variable refresh rate (VRR) mode, in other words, to be switched between a first refresh rate and a second refresh rate. For example, the controller 200 may drive each pixel P at various refresh rates by simply varying a rate of a clock signal, generating a synchronization signal, for generation of a horizontal blank or a vertical blank, or driving the gate driving circuit 300 in a mask manner.

The voltage level of the gate control signal GCS output from the controller 200 may be converted into a gate-low voltage VGL/VEL and a gate-high voltage VGH/VEH through a level shifter (not shown), and the gate-low voltage VGL/VEL and the gate-high voltage VGH/VEH may then be supplied to the gate driving circuit 300. The level shifter converts a low-level voltage of the gate control signal GCS into a gate-low voltage VGL, and converts a high-level voltage of the gate control signal GCS into a gate-high voltage VGH. The gate control signal GCS may include a start pulse and a shift clock.

The gate driving circuit 300 may supply a gate signal to each gate line GL according to a gate control signal supplied from the controller 200. The gate driving circuit 300 may be disposed at one side or both sides of the display panel 100 in a gate-in-panel (GIP) manner.

The gate driving circuit 300 sequentially outputs a gate signal to a plurality of gate lines GL under control of the controller 200. The gate driving circuit 300 may shift the gate signal using a shift register and, as such, may sequentially supply shifted gate signals to the gate lines GL, respectively.

The gate signal may include a scan signal SC and an emission control signal EM in an OLED display apparatus. The scan signal SC may include a scan pulse that swings between a gate-low voltage VGL and a gate-high voltage VGH. The emission control signal EM may include an emission control signal pulse that swings between a gate-low voltage VEL and a gate-high voltage VEH. The scan pulse selects pixels P of a line on which a data voltage Vdata will be written. The emission control signal EM defines an emission time of the pixels P.

The gate driving circuit 300 may include at least one scan driver 310 and an emission control signal driver 320.

The emission control signal driver 320 may output an emission control signal pulse in response to a start pulse and a shift clock from the controller 200, and may sequentially shift the emission control signal pulse according to the shift clock.

The at least one scan driver 310 may output a scan pulse in response to the start pulse and the shift clock from the controller 200, and may shift the scan pulse according to a timing of the shift clock.

The data driving circuit 400 may convert image data RGB into a data voltage Vdata according to a data control signal DCS supplied from the controller 200, and may supply the data voltage Vdata to the pixels P through the data lines DL.

Although the data driving circuit 400 in FIG. 1 is shown as being disposed in the form of a single data driving circuit at one side of the display panel 100, the number and position thereof may not be limited to those shown in FIG. 1. In particular, the data driving circuit 400 may include a plurality of integrated circuits (ICs) in other embodiments, and, as such, may be disposed at one side of the display panel 100 in a state of being divided into portions respectively corresponding to the plurality of ICs.

The power supply 500 may generate DC power required for driving of the pixel array and the display panel drivers of the display panel 100, using a DC-DC converter. The DC-DC converter may include a charge pump, a regulator, a buck converter, a boost converter, etc.

The power supply 500 may receive a DC input voltage from the host system (not shown), thereby generating DC voltages such as a gate-low voltage VGL/VEL, a gate-high voltage VGH/VEH, a high-level drive voltage EVDD, a low-level drive voltage EVSS, etc.

The gate-low voltage VGL/VEL and the gate-high voltage VGH/VEH may be supplied to the level shifter (not shown) and the gate driving circuit 300. The high-level drive voltage EVDD and the low-level drive voltage EVSS may be supplied to the pixels P in common.

Referring to FIGS. 1 and 2, the light emitting display apparatus 10 according to an embodiment of the present disclosure may include an active area in which an image is displayed, and a non-active area disposed around the active area.

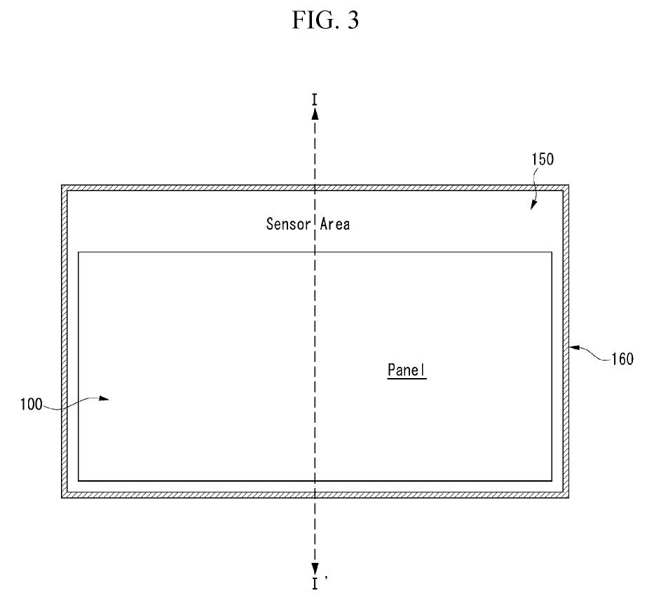

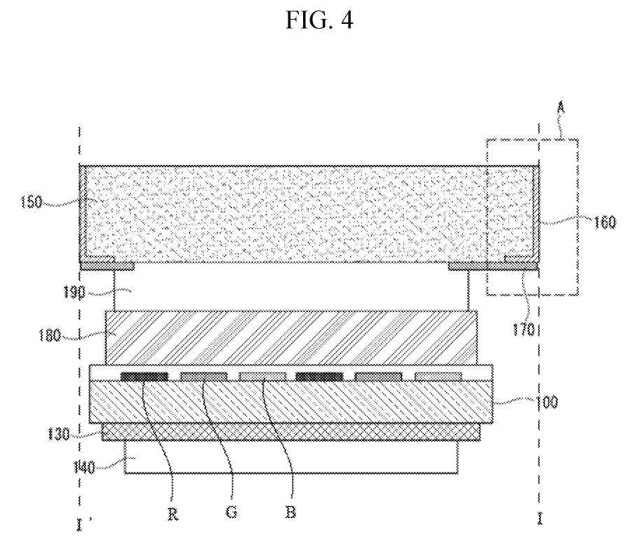

FIG. 3 is a schematic plan view of a display apparatus according to an embodiment of the present disclosure. FIG. 4 is a schematic cross-sectional view of the display apparatus according to an embodiment of the present disclosure taken along line I-I' in FIG. 3.

As shown in FIGS. 3 and 4, the display apparatus according to an embodiment of the present disclosure may include a display panel 100 configured to display an image, and a cover glass 150 disposed over the display panel 100 to protect the display panel 100.

A reflective material layer 160 may be disposed at edge portions of side and bottom surfaces of the cover glass 150. The reflective material layer 160 may be disposed to surround all side surfaces of the cover glass 150. The reflective material layer 160 may include a silver (Ag) material. The reflective material layer 160 may be formed to have a multilayer structure by combining materials such as SiO₂, TiO₂, silver (Ag), and aluminum (Al). The thickness of the reflective material layer 160 may be within about 400 to about 800 Å. The specific configuration of the reflective material layer 160 will be described later.

The cover glass 150 may be formed to have a larger area than an area of the display panel 100. One side surface of the cover glass 150 may further extend from the display panel 100, as compared to the remaining side surfaces of the cover glass 150. A sensor area may be disposed at the side surface of the cover glass 150 further extending from the display panel 100. In the sensor area of the cover glass 150, various components such as an infrared (IR) sensor, an ambient light sensor, a camera, a speaker, etc. may be mounted.

The display panel 100 may include a plurality of pixels formed on a substrate. The plurality of pixels P may be disposed in an active area of the display panel 100 and, as such, the active area is an area in which an image is displayed. Each pixel P may include a plurality of subpixels. Each subpixel may be an individual light emitting unit and, as such, may emit light of red, green, blue, or white without being limited thereto. At each subpixel in the active area, a light emitting element and a pixel circuit configured to drive the light emitting element may be disposed. The pixel circuit may include at least one thin film transistor and at least one capacitor. The light emitting element may be, for example, an organic light emitting diode or an inorganic light emitting diode.

In the display panel 100, red, green, and blue color filters R, G, and B may be disposed at red, green, and blue subpixels, respectively.

The non-active area of the display panel 100 may be an area in which an image is not displayed. In the non-active area, driving circuits and various lines for driving of the plurality of subpixels disposed in the active area may be disposed. For example, a gate driving circuit may be disposed in the non-active area. The gate driving circuit may be formed (or directly formed) in the non-active area of the display panel 100.

In an embodiment, a data driving circuit may be further disposed in the non-active area. The data driving circuit may be fabricated as an IC chip to be mounted in the non-active area of the display panel 100, or may be formed (or directly formed) in the non-active area of the display panel 100.

A black coating layer 130 may be disposed on a lower surface of the display panel 100. The black coating layer 130 may be disposed to have a narrower width than a width of the display panel 100, without being limited thereto.

A back plate 140 may be disposed on a lower surface of the black coating layer 130. The back plate 140 may be made of a metal material or a polymer film. When the back plate 140 is made of a metal material, the back plate 140 may include aluminum (Al). When the back plate 140 is made of a polymer film, the back plate 140 may be formed of polyimide (PI), polyethylene terephthalate (PET), polycarbonate (PC), or polyethylene naphthalate (PEN), without being limited thereto. When the back plate 140 is made of a metal material, the back plate 140 may also serve as a heat dissipation plate configured to dissipate heat generated from the display panel 100 to the outside.

A polarization layer 180 may be disposed on an upper surface of the display panel 100. As the polarization layer 180 is disposed on the display panel 100, the polarization layer 180 may prevent reflection of light incident from the outside, thereby enhancing outdoor visibility of the display panel 100. The polarization layer 180 may include a polarizer and a phase delay layer.

The cover glass 150 may be attached to the polarization layer 180 via an adhesive layer 190. The cover glass 150 may be made of tempered glass or a plastic film having impact resistance and light transparency to protect the display panel 100 from external impact, moisture, heat, etc. To meet the strength and foldability requirements, the cover glass 150 may have a thickness of about 30 μm to about 200 μm.

When the cover glass 150 is made of a plastic film, the cover glass 150 may include polyimide (PI), polyethylene terephthalate (PET), polypropylene glycol (PPG), and polycarbonate (PC) films, without being limited thereto.

When the cover glass 150 is made of tempered glass, the cover glass 150 may break due to external force or stress. To prevent fragments of the cover glass 150 from scattering, an anti-shattering film may be attached to an upper surface of the cover glass 150. The anti-shattering film may include, for example, a base film including polyethylene terephthalate (PET), colorless polyimide (CPI), a laminate of polyethylene terephthalate (PET) and colorless polyimide (CPI), or the like. A hard coating layer, an anti-reflection layer, a fingerprint resistant layer, etc. may be coated over an upper surface of the base film.

The adhesive layer 190 may include a pressure-sensitive adhesive including an optically clear adhesive or the like.

A black matrix 170 may be disposed on the back surface of the cover glass 150. The black matrix 170 may be disposed on a portion of the back surface of the cover glass 150 where the adhesive layer 190 is not formed. The black matrix 170 and the adhesive layer 190 may overlap each other in a predetermined region. The reflective material layer 160 may be disposed on a side surface of the cover glass 150.

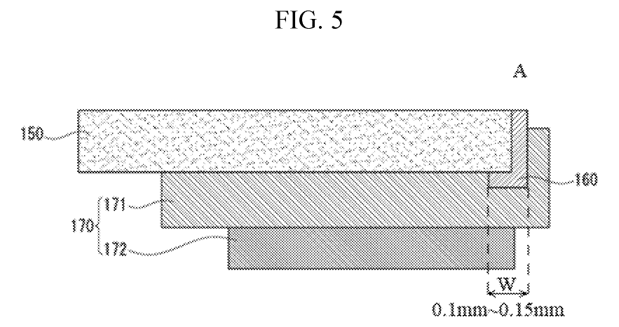

FIG. 5 is a detailed schematic configuration diagram of part "A" of FIG. 4. More particularly, FIG. 5 is a cross-sectional view of a region in the sensor area of FIG. 3 according to an embodiment where a sensor is not disposed.

As shown in FIG. 5, the reflective material layer 160 may be disposed to extend over a side surface of the cover glass 150 and a portion of the back surface of the cover glass 150 adjacent to the side surface. The width W of the reflective material layer 160 disposed on the back surface of the cover glass 150 may be about 0.1 mm to about 0.15 mm. As the reflective material layer 160 is formed to extend up to the back surface of the cover glass 150 such that the reflective material layer 160 has the above-described width, a sufficient margin may be secured, allowing the reflective material layer 160 to be formed on the side surface of the cover glass 150.

The black matrix 170 may include a first black matrix 171 and a second black matrix 172. The first black matrix 171 may be disposed to extend over side surfaces of the reflective material layer 160 and the back surface of the cover glass 150. The second black matrix 172 may be disposed on a back surface of the first black matrix 171. As the first black matrix 171 covers the side surfaces of the reflective material layer 160, it may be possible to effectively prevent a light leakage phenomenon at an edge region of the cover glass 150.

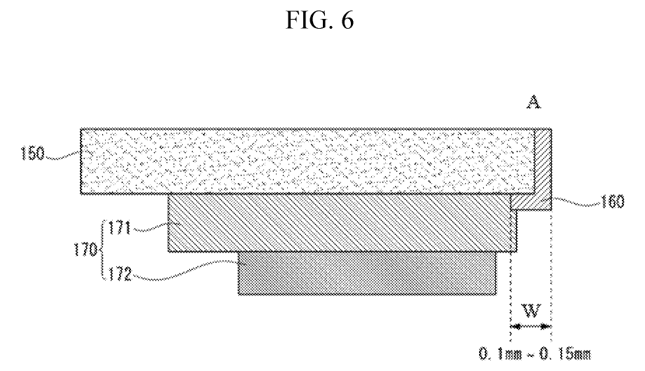

FIG. 6 is a detailed schematic configuration diagram of part "A" of FIG. 4 according to another embodiment of the present disclosure. More particularly, FIG. 6 is a schematic cross-sectional view of a region in the sensor area of FIG. 3 according to another embodiment where a sensor is not disposed.

As shown in FIG. 6, the reflective material layer 160 may be disposed to extend over a side surface of the cover glass 150 and a portion of the back surface of the cover glass 150 adjacent to the side surface.

The black matrix 170 may include a first black matrix 171 and a second black matrix 172. The first black matrix 171 may be disposed on the back surface of the cover glass 150 and may overlap an end of the reflective material layer 160 disposed on the back surface of the cover glass 150. The second black matrix 172 may be disposed on a back surface of the first black matrix 171.

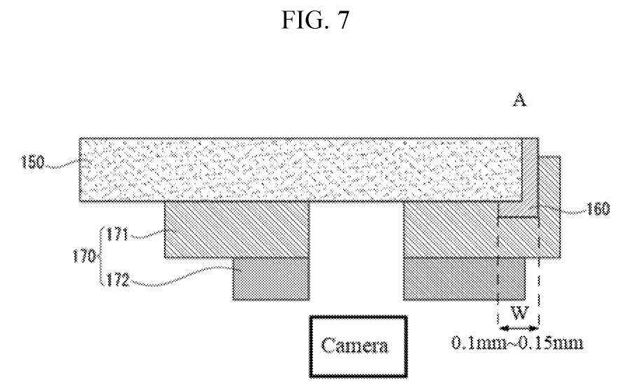

FIG. 7 is a detailed schematic configuration diagram of part "A" of FIG. 4 according to another embodiment of the present disclosure. More particularly, FIG. 7 is a schematic cross-sectional view of a region in the sensor area of FIG. 3 according to another embodiment where a camera is disposed.

As shown in FIG. 7, the configuration of the reflective material layer 160 may be the same as described with reference to FIG. 5 and, as such, a detailed description thereof is omitted.

The black matrix 170 may include a first black matrix 171 and a second black matrix 172. The first black matrix 171 may be disposed to extend over side surfaces of the reflective material layer 160 and the back surface of the cover glass 150. The second black matrix 172 may be disposed on a back surface of the first black matrix 171.

In the above-described structure, portions of the first black matrix 171 and the second black matrix 172 may be removed in the region where the camera would be disposed.

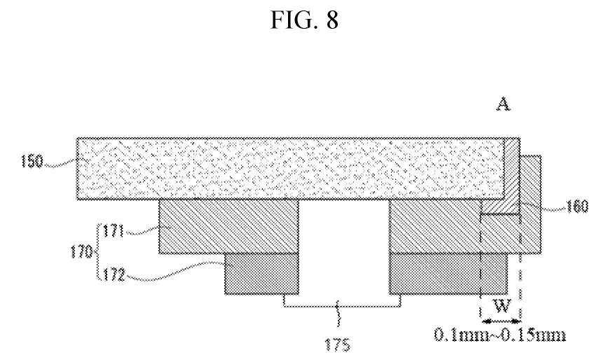

FIG. 8 is a detailed schematic configuration diagram of part "A" of FIG. 4 according to another embodiment of the present disclosure. More particularly, FIG. 8 is a schematic cross-sectional view of a region in the sensor area of FIG. 3 according to another embodiment where an infrared (IR) sensor, an ambient light sensor, or the like, except for a camera, is disposed.

The configurations of the reflective material layer 160, the first black matrix 171, and second black matrix 172 may be the same as described with reference to FIG. 7.

In the region where an infrared (IR) sensor, an ambient light sensor, or the like is disposed, portions of the first black matrix 171 and the second black matrix 172 may be removed. The region from which the first black matrix 171 and the second black matrix 172 may be removed may be filled with a sensor ink 175.

The display panel 100 may include an organic light-emitting diode (OLED) display panel, which is a self-luminous display panel.

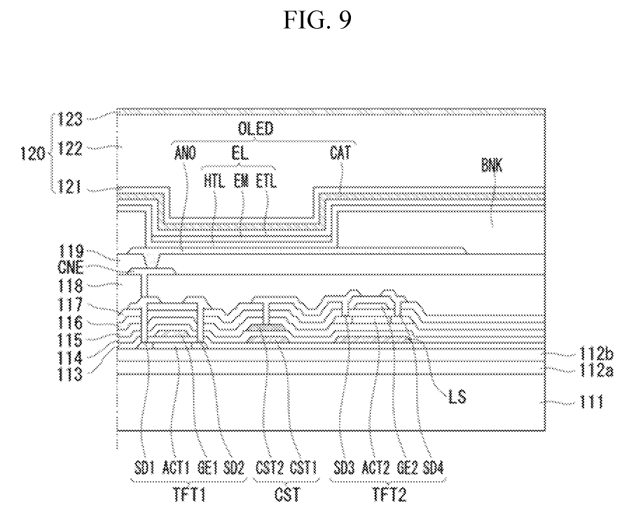

FIG. 9 is a schematic cross-sectional view of an arbitrary pixel disposed in an active area of a display panel according to an embodiment of the present disclosure.

As shown in FIG. 9, a plurality of pixels P may be disposed at a display panel 100. In each pixel area, a light emitting element OLED, transistors TFT1 and TFT2 configured to drive the light emitting element OLED, a capacitor CST, and an encapsulation layer 120 may be disposed.

The transistors TFT1 and TFT2 may include a silicon thin film transistor including a polycrystalline semiconductor material and an oxide thin film transistor including an oxide semiconductor material. In this case, the thin film transistor including the polycrystalline semiconductor material may be referred to as a polycrystalline thin film transistor TFT1, and the thin film transistor including the oxide semiconductor material may be referred to as an oxide thin film transistor TFT2. For example, the polycrystalline thin film transistor TFT1 may be a transistor connected to the light emitting element OLED, and the oxide thin film transistor TFT2 may be a transistor connected to the capacitor CST.

Conversely, the thin film transistor including a polycrystalline semiconductor material may be referred to as a polycrystalline thin film transistor TFT2, and the thin film transistor containing an oxide semiconductor material may be referred to as an oxide thin film transistor TFT1. For example, the polycrystalline thin film transistor TFT2 may be a transistor connected to the capacitor CST, and the oxide thin film transistor TFT1 may be a transistor connected to the light emitting element OLED.

In the following description, the thin film transistor including a polycrystalline semiconductor material will be referred to as a polycrystalline thin film transistor TFT1, and the thin film transistor including an oxide semiconductor material will be referred to as an oxide thin film transistor TFT2.

A substrate 111 may be a glass substrate or a flexible substrate. When the substrate 111 is a flexible substrate, the substrate 111 may be implemented to have a multilayer structure in which organic and inorganic layers are alternately laminated. For example, the substrate 111 may be formed to have a multilayer structure in which an organic layer made of, for example, polyimide, and an inorganic layer made of, for example, silicon oxide (SiO₂).

A lower buffer layer 112a may be disposed on the substrate 111. The lower buffer layer 112a may serve to block moisture, etc. that may penetrate from the outside, and may use silicon oxide (SiO₂) or the like in the form of multiple stacked layers. An auxiliary buffer layer 112b may be further disposed on the lower buffer layer 112a in a thickness direction to protect elements from permeation of moisture.

The polycrystalline thin film transistor TFT1 may be formed on the substrate 111. For example, the polycrystalline thin film transistor TFT1 may be formed on the auxiliary buffer layer 112b. A polycrystalline semiconductor may be used as an active layer of the polycrystalline thin film transistor TFT1. The polycrystalline thin film transistor TFT1 may include a first active layer ACT1 including a channel, through which electrons or holes move, a first gate electrode GE1, a first source electrode SD1, and a first drain electrode SD2. A first gate insulating layer 113 may be disposed between the first gate electrode GE1 and the first active layer ACT1. For example, the first gate electrode GE1 may overlap the first active layer ACT1 in the thickness direction. The first gate insulating layer 113 may use an inorganic layer such as a silicon oxide (SiO₂) layer, a silicon nitride (SiNₓ) layer, or the like in the form of a single layer or multiple stacked layers.

The first active layer ACT1 may include a first channel region, a first source region disposed at one side of the first channel region, and a first drain region disposed at the other side of the first channel region. Accordingly, the first channel region may be interposed between the first source region and the first drain region. The first source region and the first drain region may be regions treated to have conductivity through doping of group-V or III impurity ions such as phosphorous (P) or boron (B) ions in an intrinsic polycrystalline semiconductor material in a predetermined concentration. In the first channel region, the polycrystalline semiconductor material may be maintained in an intrinsic state and, as such, the first channel region provides a path for movement of electrons and holes.

According to an embodiment, the polycrystalline thin film transistor TFT1 may have a top-gate structure in which the first gate electrode GE1 is disposed over the first active layer ACT1. Accordingly, a first electrode CST1 included in the capacitor CST and a light shielding layer LS included in the oxide thin film transistor TFT2 may be formed using the same material as that of the first gate electrode GE1. In this case, the first gate electrode GE1, the first electrode CST1, and the light shielding layer LS may be formed through a single mask process and, as such, the number of mask processes may be reduced.

The first gate electrode GE1 may be made of a metal material. For example, the first gate electrode GE1 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

A first interlayer insulating layer 114 may be disposed on the first gate electrode GE1 and the first gate insulating layer 113. The first interlayer insulating layer 114 may be implemented using silicon oxide (SiO₂), silicon nitride (SiNₓ), or the like.

The display panel 100 may further include, at each pixel P thereof, an upper buffer layer 115, a second gate insulating layer 116, and a second interlayer insulating layer 117 sequentially disposed over the first interlayer insulating layer 114.

The first source electrode SD1 and the first drain electrode SD2 of the polycrystalline thin film transistor TFT1 may be formed on the second interlayer insulating layer 117. The first source electrode SD1 and the first drain electrode SD2 of the polycrystalline thin film transistor TFT1 may be respectively connected to the first source region and the first drain region of the first active layer ACT1 via contact holes penetrating through the first gate insulating layer 113, the first interlayer insulating layer 114, the upper buffer layer 115, the second gate insulating layer 116, and the second interlayer insulating layer 117.

The upper buffer layer 115 may provide a base for forming a second active layer

ACT2 of the oxide thin film transistor TFT2 implemented using an oxide semiconductor material while spacing the second active layer ACT2 spaced apart from the first active layer ACT1 implemented using a polycrystalline semiconductor material.

The oxide thin film transistor TFT2 may be formed on the upper buffer layer 115. The oxide thin film transistor TFT2 may include the second active layer ACT2 implemented using an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 may be implemented using an oxide semiconductor material and may include an intrinsic second channel region not doped with impurities, and a second source region and a second drain region treated to have conductivity through doping with impurities.

The oxide thin film transistor TFT2 may further include the light shielding layer LS which is disposed under the upper buffer layer 115 while overlapping the second active layer ACT2 in the thickness direction. The light shielding layer LS blocks light incident from the side of the substrate 111, thereby securing reliability of the oxide thin film transistor TFT2. The light shielding layer LS may be made of the same material as that of the first gate electrode GE1 and may be formed on an upper surface of the first gate insulating layer 113. The light shielding layer LS may be electrically connected to the second gate electrode GE2, thereby constituting a dual gate.

The second source electrode SD3 and the second drain electrode SD4 may be formed on the second interlayer insulating layer 117 simultaneously with the first source electrode SD1 and the first drain electrode SD2, using the same material as that of the first source electrode SD1 and the first drain electrode SD2. Accordingly, the number of mask processes may be reduced.

The second gate insulating layer 116 may be disposed on the second active layer ACT2 configured to cover the second active layer ACT2 of the oxide thin film transistor TFT2. Since the second gate insulating layer 116 is formed on the second active layer ACT2 implemented using an oxide semiconductor material, the second gate insulating layer 116 may be implemented using an inorganic layer. For example, the second gate insulating layer 116 may be made of silicon dioxide (SiO₂), silicon nitride (SiNₓ), or the like.

The second gate electrode GE2 may be made of a metal material. For example, the second gate electrode GE2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

Meanwhile, the first electrode CST1 may be disposed on the first gate insulating layer 113, and a second electrode CST2 may be disposed on the first interlayer insulating layer 114 to overlap the first electrode CST1 in the thickness direction, thereby implementing the capacitor CST. The first electrode CST1 may be formed of the same material as the light-shielding layer LS and the first gate electrode GE1.

The second electrode CST2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The capacitor CST may serve to store a data voltage applied thereto via a data line DL for a predetermined period. The capacitor CST may include two electrodes facing each other, and a dielectric disposed between the two electrodes. The first interlayer insulating layer 114 may be disposed between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. However, the connection relation of the capacitor CST may be varied according to the pixel driving circuit, without being limited to the above-described connection relation.

Meanwhile, a first planarization layer 118 and a second planarization layer 119 may be sequentially disposed over the polycrystalline thin film transistor TFT1, the oxide thin film transistor TFT2, and the capacitor CST1, for surface planarization in the thickness direction. The first planarization layer 118 and the second planarization layer 119 may be an organic layer made of polyimide or acrylic resin. The light emitting element OLED may be formed on the second planarization layer 119.

The light emitting element OLED may include an anode ANO, a cathode CAT, and an emission layer EL disposed between the anode ANO and the cathode CAT. When the pixel driving circuit is implemented to use a low-level voltage connected to the cathode CAT in common, the anode ANO is disposed as a separate electrode for each subpixel. Conversely, when the pixel driving circuit is implemented to use a high-level voltage in common, the cathode CAT may be disposed as a separate electrode for each sub-pixel.

The light emitting element OLED may be electrically connected to a driving element through an intermediate electrode CNE disposed on the first planarization layer 118. For example, the anode ANO of the light emitting element OLED and the first source electrode SD1 of the polycrystalline thin film transistor TFT1 may be electrically connected by the intermediate electrode CNE.

The anode ANO may be connected to the intermediate electrode CNE which is exposed through a contact hole penetrating through the second planarization layer 119. The intermediate electrode CNE may be electrically connected to the first source electrode SD1 which is exposed through a contact hole penetrating through the first planarization layer 118.

The intermediate electrode CNE may serve as a medium for interconnecting the first source electrode SD1 and the anode ANO. The intermediate electrode CNE may be formed of a conductive material such as copper (Cu), silver (Ag), molybdenum (Mo), or titanium (Ti).

The second planarization layer 119 and the intermediate electrode CNE may be omitted. When the second planarization layer 119 and the intermediate electrode CNE are omitted, the anode ANO may be directly electrically connected to the first source electrode SD1 exposed through a contact hole extending through the first planarization layer 118.

When the anode ANO is applied to a top-emission OLED display apparatus, the anode ANO may be formed to have a multilayer structure including a transparent conductive layer and an opaque conductive layer having high reflection efficiency. The transparent conductive layer may be made of a material having a relatively great work function, for example, indium tin oxide (ITO) or indium zinc oxide (IZO). The opaque conductive layer may be formed to have a single-layer structure or a multilayer structure including aluminum (Al), silver (Ag), copper (Cu), lead (Pb), molybdenum (Mo), titanium (Ti) or an alloy thereof. For example, the anode ANO may be formed to have a structure in which a transparent conductive layer, an opaque conductive layer and a transparent conductive layer are sequentially stacked or a structure in which a transparent conductive layer and an opaque conductive layer are sequentially stacked.

A bank layer BNK may be a subpixel definition layer configured to expose the anode ANO of each pixel P. The bank BNK may be formed of an opaque material (for example, a black) in order to prevent light interference between adjacent subpixels. In this case, the bank layer BNK may include a light shielding material made of at least one of a color pigment, an organic black, and a carbon.

The emission layer EL may be stacked on the anode ANO in the order or reverse order of a hole-related layer including a hole injection layer HIL and a hole transport layer HTL, an organic light emitting layer including an emission layer EM, and an electron-related layer including an electron transport layer ETL and an electron injection layer EIL. Although only the hole transport layer HTL, the emission layer EM, and the electron transport layer ETL are shown in FIG. 7, the present disclosure is not limited thereto.

The cathode CAT may be formed on upper and side surfaces of the emission layer EL while facing the anode ANO under the condition that the emission layer EL is interposed between the cathode CAT and the anode ANO. The cathode CAT may be integrally formed to cover the entirety of the active area. When the cathode CAT is applied to a top-emission type OLED display apparatus, the cathode CAT may include a transparent conductive layer made of, for example, indium tin oxide (ITO) or indium zinc oxide (IZO). When the cathode CAT is applied to a bottom-emission type OLED display apparatus, the cathode CAT may include an opaque conductive layer having a single-layer or multilayer structure including aluminum (Al), silver (Ag), copper (Cu), lead (Pb), molybdenum (Mo), titanium (Ti), or an alloy thereof. Alternatively, the cathode CAT may include a semi-transparent conductive layer having a single-layer or multilayer structure including aluminum (Al), magnesium (Mg), silver (Ag), copper (Cu), lead (Pb), molybdenum (Mo), titanium (Ti), or an alloy thereof.

Additionally, an encapsulation layer 120 configured to suppress moisture penetration may be further disposed on the cathode electrode CAT. The encapsulation layer 120 may prevent penetration of ambient moisture or oxygen into the emission layer EL weak against ambient moisture or oxygen. For this function, the encapsulation layer 120 may include at least one inorganic encapsulation layer and at least one organic encapsulation layer, without being limited thereto. The encapsulation layer 120 may include a first encapsulation layer 121, a second encapsulation layer 122, and a third encapsulation layer 123 which are sequentially stacked in the thickness direction.

The first encapsulation layer 121 and the third encapsulation layer 123 may be formed of an inorganic insulating material depositable at a low temperature, such as silicon nitride (SiNₓ), silicon oxide (SiOₓ), silicon oxynitride (SiON), or aluminum oxide (Al₂O₃). Since the first encapsulation layer 121 and the third encapsulation layer 123 are deposited in a low-temperature atmosphere, it may be possible to prevent the emission layer EL weak against a high-temperature atmosphere from being damaged during a deposition process for the first encapsulation layer 121 and the third encapsulation layer 123.

The second encapsulation layer 122 may perform a buffering function configured to alleviate stress generated between adjacent layers due to bending of the display apparatus 10, and may planarize steps of adjacent layers. The second encapsulation layer 122 may be formed of a non-photosensitive organic insulating material such as acrylic resin, epoxy resin, phenolic resin, polyamide resin, polyethylene or silicon oxycarbide (SiOC), or a photosensitive organic insulating material such as photoreactive acrylic resin, without being limited thereto.

Although not shown, a touch sensor may be further disposed on the encapsulation layer 120. When a touch sensor is disposed on the encapsulation layer 120, the red color filter R, the green color filter G, and the blue color filter B described with reference to FIG. 4 may be disposed over the touch sensor.

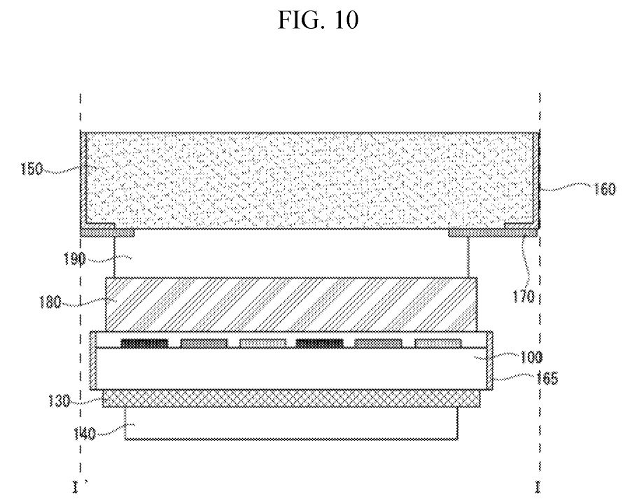

FIG. 10 is a cross-sectional view of a display apparatus according to another embodiment of the present disclosure taken along line I-I' in FIG. 3.

In the display apparatus according to another embodiment, a reflective material layer may be further disposed on a side surface of a display panel, as shown in FIG. 10.

The display apparatus according to another embodiment of the present disclosure may include a display panel 100, a black coating layer 130, a back plate 140, a polarization layer 180, an adhesive layer 190, a cover glass 150, a black matrix 170, and a reflective material layer 160 which are identical to those described with reference to FIG. 4.

Additionally, another reflective material layer 165 may be disposed on all side surfaces of the display panel 100. The reflective material layer 165 and the reflective material layer 160 may be made of the same material.

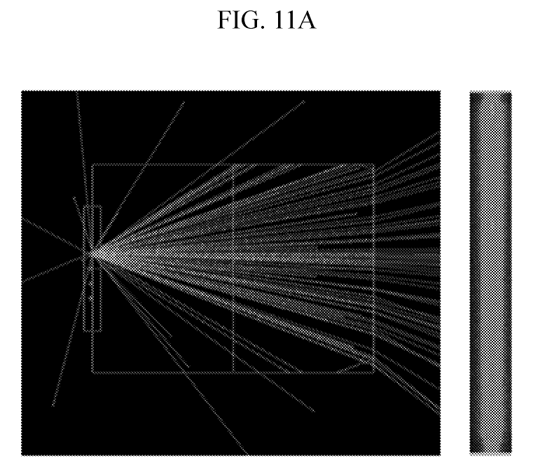

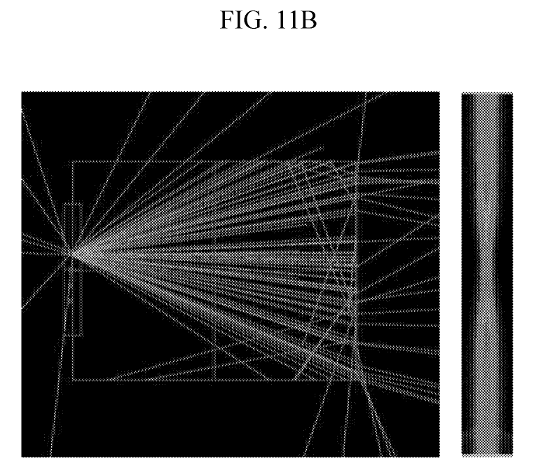

FIGS. 11A and 11B are schematic results of a simulation associated with light loss in a display apparatus according to an embodiment of the present disclosure and a comparative example. FIG. 11A schematically shows simulation results associated with light loss in a display apparatus according to the comparative example, and FIG. 11B schematically shows simulation results associated with light loss in the display apparatus according to an embodiment of the present disclosure.

In particular, FIG. 11A schematically shows simulation results associated with light loss in a display apparatus in the case in which the reflective material layer 160 according to an embodiment of the present disclosure is not disposed on a side surface of the cover glass 150. FIG. 11B schematically shows simulation results associated with light loss in the case in which the reflective material layers 160 and 165 are disposed on side surfaces of the cover glass 150 and the display panel 100 according to the embodiment of the present disclosure.

Comparison between FIGS. 11A and 11B may demonstrate that, in the case in which the reflective material layers 160 and 165 are disposed on the side surfaces of the cover glass 150 and the display panel 100 according to the embodiment of the present disclosure, side light loss is reduced by about about 63%, as compared to the case in which no reflective material layer is disposed. In the display apparatus according to an embodiment of the present disclosure, accordingly, it may be possible to enhance vertical luminance and to prevent sensor malfunctions caused by light leaking from side surfaces entering various sensors.

Additionally, in the case in which the reflective material layers 160 and 165 are disposed on the side surfaces of the cover glass 150 and the display panel 100, printing peel-off may be minimized, as compared to the case in which no reflective material layer is disposed.

As apparent from the above description, as a reflective material layer is disposed on a side surface of a cover glass of a display apparatus used in mobile and IT products, light leakage may be prevented and luminance may be increased. Additionally, it may be possible to prevent malfunctions of various sensors disposed within the display apparatus.

Since a reflective material layer is also disposed on a side surface of a display panel of the display apparatus used in mobile and IT products, light leakage may be further suppressed, and luminance may be further enhanced.

According to embodiments of the present disclosure, a reflective material layer is disposed on a side surface of the cover glass of the display apparatus used in mobile and IT products. Accordingly, light leakage may be prevented and luminance may be increased. Additionally, it may be possible to prevent malfunctions of various sensors disposed within the display apparatus.

The reflective material layer is also disposed on a side surface of the display panel of the display apparatus used in mobile and IT products. Accordingly, light leakage may be further suppressed, and luminance may be further enhanced.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a display panel configured to display an image;
a cover glass disposed over the display panel; and
a first reflective material layer disposed on a side surface of the cover glass.

2. The display apparatus of claim 1, wherein the first reflective material layer is disposed on all side surfaces of the cover glass.

3. The display apparatus of claim 1, wherein the first reflective material layer is disposed to cover all side surfaces of the cover glass and a portion of a bottom surface of the cover glass adjacent to the side surface of the cover glass.

4. The display apparatus of claim 1, further comprising:
a second reflective material layer disposed on a surface of the display panel.

5. The display apparatus of claim 4, wherein the first reflective material layer or the second reflective material layer includes silver (Ag).

6. The display apparatus of claim 4, wherein the first reflective material layer or the second reflective material layer is formed of a combination of materials selected from SiO₂ TiO₂ silver (Ag), and aluminum (Al) to have a multilayer structure.

7. The display apparatus of claim 4, wherein the first reflective material layer or the second reflective material layer has a thickness of about 400 Å to about 800 Å.

8. The display apparatus of claim 4, further comprising:
a black coating layer disposed on a lower surface of the display panel;
a back plate disposed on a lower surface of the black coating layer; and
a polarization layer disposed on an upper surface of the display panel,
wherein the cover glass is attached to the polarization layer by an adhesive layer.

9. The display apparatus of claim 8, further comprising:
a black matrix disposed on a back surface of the cover glass.

10. The display apparatus of claim 9, wherein the black matrix is disposed on a portion of the back surface of the cover glass where the adhesive layer is not formed.

11. The display apparatus of claim 9, wherein the black matrix and the adhesive layer overlap each other in a predetermined region.

12. The display apparatus of claim 9, wherein the black matrix includes:
a first black matrix disposed to cover a side surface of the first reflective material layer and the back surface of the cover glass; and
a second black matrix disposed on a back surface of the first black matrix.

13. The display apparatus of claim 9, wherein the black matrix includes:
a first black matrix disposed on the back surface of the cover glass while overlapping an end of the first reflective material layer disposed on the back surface of the cover glass; and
a second black matrix disposed on a back surface of the first black matrix.

14. A display apparatus comprising:
a display panel configured to display an image;
a cover glass disposed over the display panel;
a first reflective material layer disposed on side and bottom surfaces of the cover glass; and
a second reflective material layer disposed on a surface of the display panel.

15. The display apparatus of claim 14, further comprising:
a black coating layer disposed on a lower surface of the display panel;
a back plate disposed on a lower surface of the black coating layer; and
a polarization layer disposed on an upper surface of the display panel,
wherein the cover glass is attached to the polarization layer by an adhesive layer.

16. The display apparatus of claim 15, further comprising:
a black matrix disposed on a back surface of the cover glass.

17. The display apparatus of claim 16, wherein the black matrix is disposed on a portion of the back surface of the cover glass where the adhesive layer is not formed.

18. The display apparatus of claim 16, wherein the black matrix and the adhesive layer overlap each other in a predetermined region.

19. The display apparatus of claim 16, wherein the black matrix comprises:
a first black matrix disposed to extend over a side surface of the first reflective material layer and the back surface of the cover glass; and
a second black matrix disposed on a back surface of the first black matrix.

20. The display apparatus of claim 16, wherein the black matrix comprises:
a first black matrix disposed on the back surface of the cover glass while overlapping with an end of the first reflective material layer disposed on the back surface of the cover glass; and
a second black matrix disposed on a back surface of the first black matrix.
